(19) United States
(12) Patent Application Publication
(10) Pub. No.: US 2023/0094622 A1
(43) Pub. Date: Mar. 30, 2023

(54) GATE VALVE, SUBSTRATE PROCESSING SYSTEM, AND METHOD OF OPERATING GATE VALVE

(71) Applicant: Tokyo Electron Limited, Tokyo (JP)

(72) Inventor: Tsutomu HIROKI, Nirasaki City (JP)

(21) Appl. No.: 17/949,520

(22) Filed: Sep. 21, 2022

(30) Foreign Application Priority Data
Sep. 29, 2021 (JP) 2021-159989

(51) Int. Cl. F16K 3/18; F16K 31/04; F16K 3/02; C23C 16/458; C23C 16/54

(52) U.S. Cl. CPC F16K 3/18; F16K 31/047; F16K 3/0254; C23C 16/4583; C23C 16/54

(57) ABSTRACT

A gate valve provided in a boundary portion between two sections to block communication between the two sections, the gate valve includes a base, a first moving mechanism installed on the base and configured to move a first movement body along a first linear track, a second moving mechanism installed on the first movement body, and configured to operate at a timing different from the first moving mechanism and to move a second movement body along a second linear track orthogonal to the first linear track, and a valve body installed on the second movement body and configured to come into contact with a contact surface so as to perform sealing. One of the first linear track and the second linear track is parallel to a direction orthogonal to the contact surface.

### CROSS-REFERENCE TO RELATED APPLICATION

This application is based upon and claims the benefit of priority from Japanese Patent Application No. 2021-159989, filed on Sep. 29, 2021, the entire contents of which are incorporated herein by reference.

### TECHNICAL FIELD

The present disclosure relates to a substrate processing system and a method of operating a gate valve.

### BACKGROUND

A gate valve is provided at a boundary portion between a process module for processing a substrate and a transport module for transporting the substrate, and the communication between the process module and the transport module is cut off by a seal. This type of gate valve is required to be sealed in an appropriate pressing direction with an appropriate pressing force in order to increase the durability of the sealing material that seals the structure for communication.

For example, in the gate valve disclosed in Patent Document 1, after a valve body is moved in a vertical direction by a first drive device, the valve body performs sealing by being moved in a horizontal direction by a second drive device located at a position different from that of the first drive device. The gate valve disclosed in Patent Document 2 performs sealing in a vertical direction by a sealing material provided on a step in the upper portion of a valve body as the valve body moves in the vertical direction.

### PRIOR ART DOCUMENTS

### Patent Documents

Patent Document 1: Japanese Laid-Open Publication No. 2013-231461

Patent Document 2: Japanese Laid-Open Publication No. 2007-309337

### SUMMARY

An aspect of the present disclosure provides a gate valve provided in a boundary portion between two sections to block communication between the two sections, the gate valve including: a base; a first moving mechanism installed on the base and configured to move a first movement body along a first linear track; a second moving mechanism installed on the first movement body, and configured to operate at a timing different from the first moving mechanism and to move a second movement body along a second linear track orthogonal to the first linear track; and a valve body installed on the second movement body and configured to come into contact with a contact surface so as to perform sealing, wherein one of the first linear track and the second linear track is parallel to a direction orthogonal to the contact surface.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic plan view illustrating an example of an overall configuration of a substrate processing system.

FIG. 2 is a schematic side view illustrating portions of a boundary portion in which a gate valve is installed, and a process module and a transport module.

FIG. 3 is a schematic perspective view illustrating each component of the gate valve according to the first embodiment.

FIG. 4A is a schematic side view illustrating each component of the gate valve of FIG. 3, and FIG. 4B is a schematic view of the gate valve viewed from the direction indicated by arrow A in FIG. 4A.

FIG. 5 is a schematic vertical cross-sectional view illustrating a differential screw mechanism applied to a horizontal actuator.

FIG. 6A is a flowchart illustrating the closing operation of the gate valve, and FIG. 6B is an explanatory view illustrating the closing operation of the valve body.

FIG. 7A is a flowchart illustrating the opening operation of the gate valve, and FIG. 7B is an explanatory view illustrating the opening operation of the valve body.

FIG. 8 is a schematic perspective view illustrating each component of the gate valve according to a second embodiment.

FIG. 9 is a schematic side view of the gate valve of FIG. 8.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each of the drawings, the same components may be denoted by the same reference numerals, and redundant descriptions thereof may be omitted.

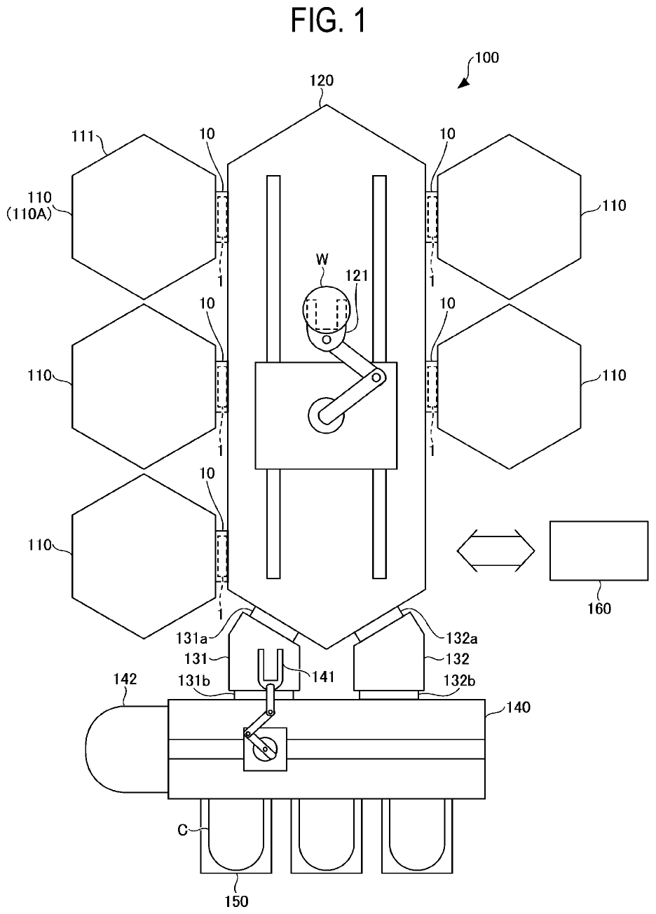

FIG. 1 is a schematic plan view illustrating an overall configuration example of a substrate processing system 100. As illustrated in FIG. 1, the substrate processing system 100 is a semiconductor manufacturing apparatus having a cluster structure (multi-chamber type) including a plurality of process modules 110, each of which processes a wafer W, which is an example of a substrate. The plurality of process modules 110 are depressurized to an appropriate vacuum atmosphere, and each execute a predetermined process (a cleaning process, an etching process, a film forming process, or the like) on a wafer W.

In addition, the substrate processing system 100 includes a transport module 120, a plurality of load-lock parts 131 and 132, a load module 140, a load port 150, and a controller 160 in addition to respective process modules 110. In the substrate processing system 100, each process module 110 (first section) and the transport module 120 (second section) are disposed adjacent to each other. The substrate processing system 100 includes a gate valve 1 for opening/closing each process module 110 at the boundary portion 10 between the process module 110 and the transport module 120.

The transport module 120 of the substrate processing system 100 is connected to a plurality of chambers (the process modules 110, and the load-lock parts 131 and 132) and depressurized to a predetermined vacuum atmosphere. The transport module 120 includes therein a vacuum transport device 121 that transports a wafer W. The vacuum transport device 121 performs carry-in/out of a wafer W between each process module 110 and the transport module 120 in response to the opening of the gate valve 1 of each process module 110. The vacuum transport device 121 performs carry-in/out of a wafer W between each load-lock part 131 or 132 and the transport module 120 in response to the opening of the gate valve 131a or 131a of each load-lock part 131 or 132.

Each load-lock part 131 or 132 is provided between the transport module 120 and the load module 140, and switches the room thereof between an atmospheric atmosphere and a vacuum atmosphere. Each load-lock part 131 or 132 includes a stage (not illustrated) on which a wafer W is placed, a gate valve 131a or 132a on the transport module 120 side, and a door valve 131b or 132b on the load module 140 side. Each load-lock part 131 or 132 communicates with the transport module 120 by opening/closing the gate valve 131b or 132b in a vacuum atmosphere. In addition, each of the load-lock parts 131 and 132 communicates with the load module 140 by opening/closing the door valve 131b or 132b in the air atmosphere state.

The load module 140 has an air atmosphere, for example, and is provided with a downflow of clean air. The load module 140 includes an atmospheric transport device 141 that transports a wafer W and an aligner 142 that performs positioning of the wafer W.

The wall surface of the load module 140 is provided with a load port 150. A carrier C accommodating a wafer W or an empty carrier C is installed in the load port 150. As the carrier C, for example, a front opening unified pod (FOUP) may be used.

The atmospheric transport device 141 performs carry-in/out of a wafer W between each load-lock part 131 or 132 and the load module 140 in response to the opening/closing of each door valve 131b or 132b. In addition, the atmospheric transport device 141 performs carry-in/out of a wafer W between the aligner 142 and the load module 140. The atmospheric transport device 141 performs carry-in/out of a wafer W between the carrier C installed in the load port 150 and the load module 140.

The controller 160 is a control computer including one or more processors, a memory, an input/output interface, and an electronic circuit (not illustrated). The controller 160 instructs each process module 110 to process a wafer W and controls the transport of the wafer W by executing a program and a recipe stored in the memory by the processor. Specifically, the controller 160 first controls the atmospheric transport device 141 and the vacuum transport device 121 to position the wafer W of the carrier C provided in the load port 150 by the aligner 142 and then deliver the wafer W to the transport module 120 via the load-lock part 131.

Then, the controller 160 controls the vacuum transport device 121 to perform carry-in/out of the wafer W from the transport module 120 to each process module 110. The controller 160 performs a predetermined process (a cleaning process, an etching process, a film forming process, or the like) on the wafer W transported to each process module 110. After processing the wafer W by one or more process modules 110, the controller 160 carries out the wafer W to the load module 140 via the transport module 120 and the load-lock part 132. Then, the atmospheric transport device 141 carries the processed wafer W into the empty carrier C.

For example, a predetermined process module 110A among respective process modules 110 is configured to perform a film forming process (CVD) in which raw-material gases are chemically reacted to deposit a thin film on the surface of the wafer W. In this case, the process module 110A includes a processing container 111 that has a vacuum atmosphere and is capable of getting a high temperature.

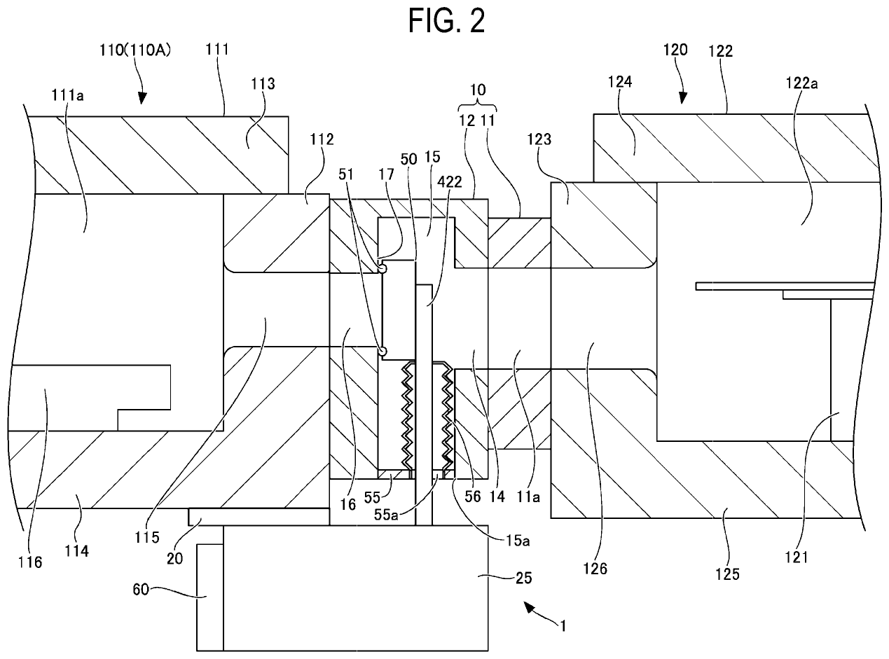

FIG. 2 is a schematic side view illustrating a boundary portion 10 in which a gate valve 1 is installed, and portions of a process module 110A and a transport module 120. As illustrated in FIG. 2, the processing container 111 is made of, for example, aluminum, and includes a side wall 112, a ceiling wall 113 and a bottom wall 114. The side wall 112 of the processing container 111 that faces the transport module 120 is provided with a process-side opening 115 that allows the processing space 111a of the processing container 111 and the boundary portion 10 to communicate with each other.

Inside the processing container 111, a stage 116 configured to hold a wafer W thereon is provided. The process module 110A, which performs a film forming process, includes a plasma generation part that generates plasma, a gas supply part that supplies a plasma excitation gas and a raw-material gas, and a gas discharge part that discharges gases, and the like (all of which are not illustrated).

Meanwhile, the transport module 120 includes a housing 122 in which an internal space 122a accommodating the vacuum transport device 121 is formed. The housing 122 is formed in a box shape including a side wall 123, a ceiling wall 124, and a bottom wall 125. A transport-side opening 126, which allows the internal space 122a and the boundary portion 10 to communicate with each other, is provided in the side wall 123 of the housing 122 at a position facing each process module 110 (the process module 110A). For example, the opening area of the transport-side opening 126 is formed larger than the opening area of the process-side opening 115.

Each process-side opening 115 and each transport-side opening 126 are used to carry a wafer W from the transport module 120 to each process module 110, and carry out a wafer W from each of the process modules 110 to the transport module 120. The gate valve 1 provided at the boundary portion 10 enables carry-in and carry-out of the wafer W by opening the boundary portion 10, and enables a process such as depressurization in the process module 110 by closing the boundary portion 10.

The boundary portion 10 includes a heat insulating member 11 provided adjacent to the housing 122 of the transport module 120, and a block body 12 provided between the heat insulating member 11 and the processing container 111 of the process module 110. Inside the heat insulating member 11 and the block body 12, a communication space interconnecting the process-side opening 115 and the transport-side opening 126 is formed. The boundary portion 10 may take an appropriate configuration in consideration of the temperature during the process in the process module 110, and may not be provided with, for example, the heat insulating member 11.

The heat insulating member 11 is formed of a material having a low thermal conductivity (a resin material or a metal material such as stainless steel), and has a flat tubular shape (an annular shape). The heat insulating member 11 insulates between the process module 110 and the transport module 120. Inside the heat insulating member 11, a communication hole 11a constituting the communication space is provided. The communication hole 11a is formed to have substantially the same cross-sectional shape as the opening shape of the transport-side opening 126.

The block body 12 is formed of, for example, a metal material such as an aluminum alloy or stainless steel, and has a cylindrical shape that is longer in the vertical direction than the heat insulating member 11. In addition, the thickness of the block body 12 along the extending direction of the communication space (the direction in which the process module 110 and the transport module 120 are arranged) is thicker than the thickness of the heat insulating member 11.

Inside the block body 12, a transport-side space 14, an accommodation space 15, and a process-side space 16 constituting the communication space are provided. That is, the communication space in the boundary portion 10 includes the communication hole 11a, the transport-side space 14, the accommodation space 15, and the process-side space 16 in that order from the transport module 120 toward each process module 110.

The transport-side space 14 is formed to have substantially the same cross-sectional shape as the cross-sectional shape of the communication hole 11 a of the heat insulating member 11 (the opening shape of the transport-side space 14), and allows the communication hole 11a and the accommodation space 15 to communicate with each other. The process-side space 16 is formed to have substantially the same cross-sectional shape as the opening shape of the process-side opening 115, and allows the process-side opening 115 and the accommodation space 15 to communicate with each other.

The accommodation space 15 provided between the transport-side space 14 and the process-side space 16 accommodates the valve body 50 of the gate valve 1 such that the valve body 50 can move therein. The accommodation space 15 extends vertically in the block body 12 and has a larger volume than the transport-side space 14 and the process-side space 16. The thickness of the accommodation space 15 (the dimension in the direction orthogonal to the vertical direction) is set to be slightly larger than the thickness of the valve body 50.

The inner surface that defines the accommodation space 15 in the block body 12 and is located on the process module 110 side has a contact surface 17 with which the valve body 50 of the gate valve 1 comes into contact. The contact surface 17 is continuously flush with the inner surface of the block body 12 extending in parallel to the vertical direction and surrounds the periphery of the process-side space 16. The contact surface 17 refers to a region shorter than the short side of the process-side space 16 from the edge of the process-side space 16, although it depends on the size of the valve body 50. The block body 12 has an open portion 15a at the lower end of the accommodation space 15, and the open portion 15a is closed by the structure of the gate valve 1. Hereinafter, the configuration of the gate valve 1 will be specifically described with reference to two embodiments.

### First Embodiment

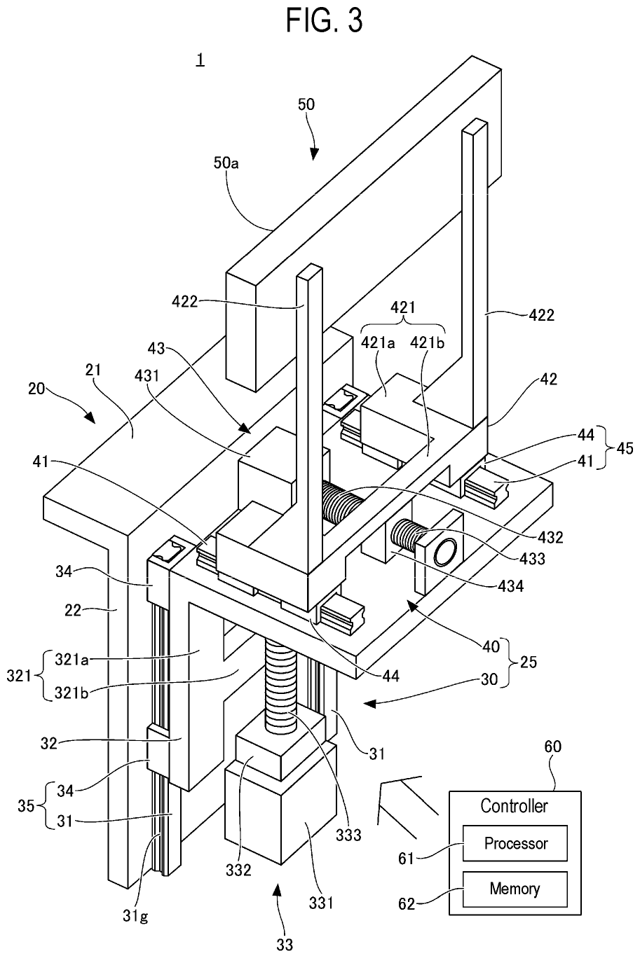

As illustrated in FIG. 2, the gate valve 1 includes a base 20 and an operation mechanism part 25 (a first moving mechanism 30 and a second moving mechanism 40) fixed to the base 20 at a position adjacent to the outer side of the boundary portion 10 (see also FIG. 3). The gate valve 1 includes a valve body 50 disposed in the accommodation space 15 in the boundary portion 10, and a controller 60 that controls the gate valve 1 in the exterior of the boundary portion 10 and the process module.

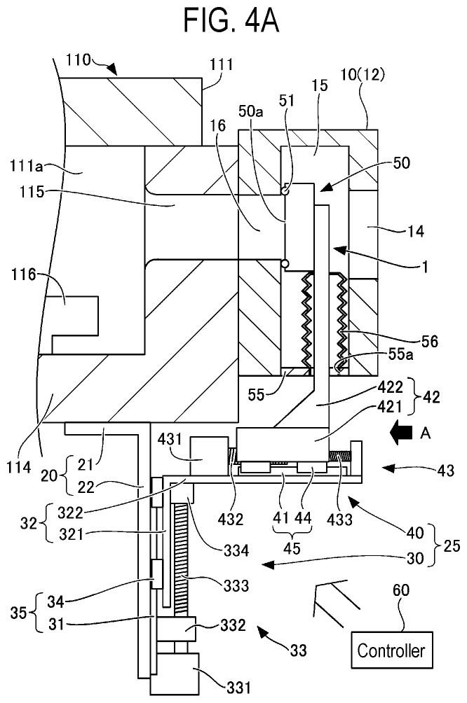

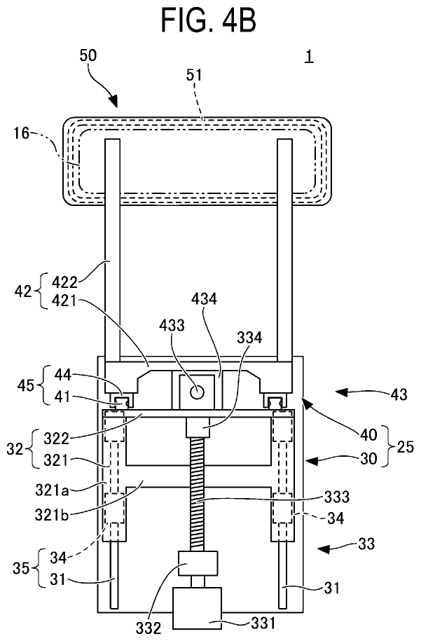

FIG. 3 is a schematic perspective view illustrating each component of the gate valve 1 according to the first embodiment. FIG. 4A is a schematic side view illustrating each component of the gate valve 1 of FIG. 3, and FIG. 4B is a schematic view of the gate valve 1 viewed from the direction indicated by arrow A in FIG. 4A. As illustrated in FIGS. 3 and FIGS. 4A and 4B, the base 20 fixes and supports the operation mechanism part 25 of the gate valve 1 outside and below the process module 110A. The base 20 includes a fixed plate portion 21 fixed to the processing container 111 of the process module 110A, and a guide plate portion 22 extending from the fixed plate portion 21. The fixed plate portion 21 and the guide plate portion 22 are connected at right angles to each other and have an L-shape when viewed from the side. The base 20 is not limited to the configuration fixed to the process module 110A, and may be fixed to the transport module 120.

The fixed plate portion 21 is installed to the bottom wall 114 of the processing container 111 by an appropriate fixing means (screw fastening, welding, and the like). The guide plate portion 22 extends along the vertical direction and holds the first moving mechanism 30 on the plate surface facing the transport module 120 side. The length of the guide plate portion 22 along the vertical direction may be appropriately set depending on the moving distance of the valve body 50 in the vertical direction.

The first moving mechanism 30 reciprocates the valve body 50 of the gate valve 1 along the vertical direction (a first linear track: height direction). The first moving mechanism 30 includes a vertical guide rail 31 installed on the guide plate portion 22, a vertical movement body 32 that moves along the vertical guide rail 31, and a vertical actuator 33 that moves the vertical movement body 32.

A plurality (e.g., a pair) of vertical guide rails 31 are installed on the guide plate portions 22, and extend in parallel to each other along the vertical direction. The number of vertical guide rails 31 to be installed is not particularly limited, and may be only one.

The vertical movement body 32 includes a vertical frame portion 321 extending in parallel to the guide plate portion 22 (in the vertical direction), a horizontal table portion 322 orthogonally connected to the vertical frame portion 321 and extending in the horizontal direction. The vertical frame portion 321 includes a plurality of vertical plate portions 321a provided to correspond to the plurality of vertical guide rails 31, and a horizontal plate portion 321b extending in the horizontal direction to bridge the plurality of vertical plate portions 321a.

The vertical frame portion 321 includes a plurality of (a pair of upper and lower) guide members 34 installed on each of the plurality of vertical guide rails 31. For example, the guide members 34 include a plurality of spheres (not illustrated) that are rollable in the guide grooves 31g provided on opposite sides of the vertical guide rail 31 in the width direction. The guide members 34 move on the vertical guide rails 31 while preventing the vertical movement body 32 from being separated in the horizontal direction since the plurality of spheres are engaged with the vertical guide rails 31. That is, the vertical guide rails 31 and the guide members 34 constitute linear motion bearings 35 that linearly move the vertical movement body 32 along the vertical direction (a first linear track).

The horizontal table portion 322 is formed in a flat plate shape extending in the horizontal direction below the processing container 111 of the process module 110A and the block body 12 of the boundary portion 10. The second moving mechanism 40 is fixed to the top surface of the horizontal table portion 322. The vertical actuator 33 is connected to the bottom surface of the horizontal table portion 322.

As the vertical actuator 33, an appropriate drive mechanism (a ball screw drive part, a fluid pressure cylinder, a linear slider, or the like) that moves the vertical movement body 32 up and down along the vertical direction (the first linear track) is applicable. A ball screw drive part is applied to the vertical actuator 33 according to the present embodiment.

The vertical actuator 33 includes a motor 331 fixed to the guide plate portion 22, a deceleration mechanism 332 provided on the motor 331, a ball screw 333 connected to the deceleration mechanism 332, and a nut 334 screw-coupled to the ball screw 333 and fixed to the vertical movement body 32. The motor 331 is fixed to the widthwise central portion of the lower end portion of the guide plate portion 22. The motor 331 is connected to the controller 60 of the gate valve 1 via a motor driver (not illustrated), and the rotation of the motor 331 is controlled in response to the control command of the controller 60. The deceleration mechanism 332 decelerates the rotation speed of the motor 331 at a predetermined reduction ratio to rotate the ball screw 333.

The ball screw 333 extends from the deceleration mechanism 332 upward in the vertical direction. The nut 334 converts the rotational movement of the ball screw 333 into a linear motion along the vertical direction. As a result, in the vertical actuator 33, since the ball screw 333 rotates in response to the rotation of the motor 331, the nut 334 and the vertical movement body 32 are displaced in the vertical direction.

Meanwhile, the second moving mechanism 40 reciprocates the valve body 50 of the gate valve 1 along a contact/separation direction (a second linear track) in which the valve body 50 comes into and separates from the contact surface 17. The second moving mechanism 40 includes a horizontal guide rail 41 installed on the horizontal table portion 322, a horizontal movement body 42 that moves along the horizontal guide rail 41, and a horizontal actuator 43 that moves the horizontal movement body 42.

A plurality (e.g., a pair) of horizontal guide rails 41 are installed on the horizontal table portion 322 and extend in parallel to each other along the contact/separation direction. The number of horizontal guide rails 41 to be installed is not particularly limited, and may be only one.

The horizontal movement body 42 includes a horizontal frame portion 421 extending in parallel to the horizontal table portion 322, and supports 422 that stand up from the horizontal frame portion 421 and support the valve body 50 at the upper end portions thereof. The horizontal frame portion 421 includes a plurality of side portions 421a provided to correspond to the horizontal guide rails 41, and a connecting portion 421b extending in the width direction to bridge the plurality of side portions 421a. In addition, the horizontal actuator 43 is connected to the horizontal frame portion 421 (the connecting portion 421b).

The horizontal frame portion 421 also includes a plurality of guide members 44 installed on the plurality of horizontal guide rails 41, respectively. The guide members 34 may have the same configuration as the guide members 34 of the first moving mechanism 30. That is, the horizontal guide rails 41 and the guide members 44 constitute linear motion bearings 45 that linearly move the horizontal movement body 42 along the horizontal direction (the contact/separation direction: the second linear track).

The supports 422 are a plurality (e.g., a pair) of solid rod-shaped members provided on the horizontal frame portion 421, and extend upward from the horizontal frame portion 421 in the vertical direction. Each support 422 is inserted into the accommodation space 15 from the outer lower position of the boundary portion 10 (the block body 12) through the open portion 15a in the block body 12, and supports the valve body 50 in the width direction in the accommodation space 15. The lower side of each support 422 is formed in a triangular shape extending along the contact/separation direction in order to increase the rigidity of the support 422 in the vertical direction.

The gate valve 1 includes, at the connection place with the block body 12, a closing member 55 that closes the open portion 15a, and a plurality of bellows 56 inserted into the accommodation space 15 from a plurality of support holes 55a formed in the closing member 55 to cover respective supports 422. The closing member 55 and each bellows 56 block the accommodation space 15 from the exterior of the block body 12. Each support hole 55a is a hole into which the support 422 is inserted, and is formed as an elongated hole in which the support 422 is movable along the contact/separation direction. Each bellows 56 is fixed to the peripheral edge of the closing member 55 surrounding each support hole 55a, and is formed in a cylindrical bellows that is expandable/contractible along the vertical direction. Each bellows 56 is flexible and allows movement of each support 422 along the contact/separation direction while maintaining the state of covering of each support 422.

As the horizontal actuator 43, an appropriate actuator (a ball screw drive part, a fluid pressure cylinder, a linear slider, or the like) that reciprocates the horizontal movement body 42 along the contact/separation direction (the second linear track) is applicable. A ball screw drive part including a differential screw mechanism 430 is applied to the horizontal actuator 43 according to the present embodiment.

The horizontal actuator 43 includes a motor 431 fixed to the horizontal table portion 322, a first screw 432 connected to the motor 431, a second screw 433 screw-coupled into the first screw 432, and a slider 434 screw-coupled to the second screw and fixed to the horizontal movement body 42. The motor 431 is fixed to the widthwise central portion of one end portion of the horizontal table portion 322. The motor 431 is connected to the controller 60 of the gate valve 1 via a motor driver (not illustrated), and the rotation of the motor 431 is controlled in response to a control command from the controller 60.

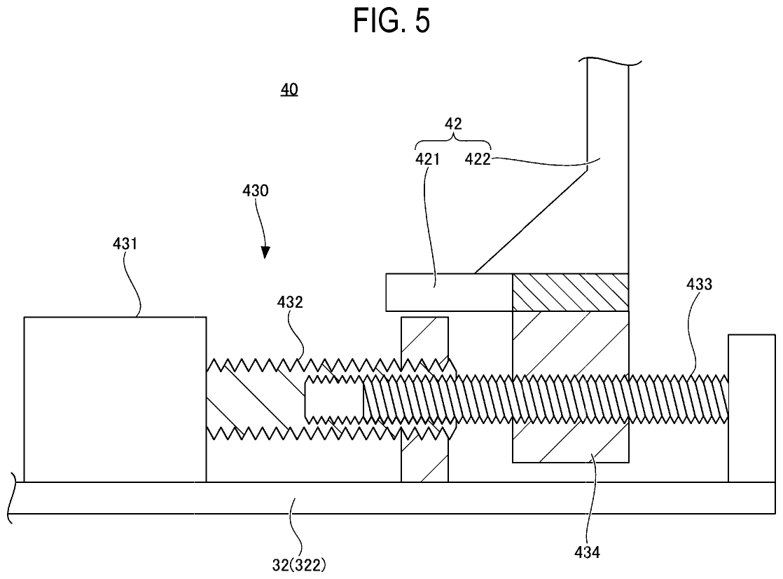

FIG. 5 is a schematic vertical cross-sectional view illustrating the differential screw mechanism 430 applied to the horizontal actuator 43. As illustrated in FIG. 5, the first screw 432, the second screw 433, and the slider 434 constitute a differential screw mechanism 430 that finely feeds the slider 434 along the contact/separation direction. The differential screw mechanism 430 rotates the second screw 433 while moving the second screw 433 in the axial direction in response to the rotation of the first screw 432. The slider 434 is screw-coupled to the outer peripheral surface of the second screw 433, and slides in a movement distance shorter than the axial movement distance of the second screw 433 as the second screw 433 rotates. As a result, the horizontal movement body 42 is movable with high accuracy in a minute range in the contact/separation direction.

The valve body 50 of the gate valve 1 is formed in a rectangular cuboid which has a size larger than the cross-sectional shape of the transport-side space 14. Specifically, the valve body 50 is short in the vertical direction, long in the width direction (horizontal direction orthogonal to the contact/separation direction), and has an appropriate thickness along the contact/separation direction. A sealing material 51 is provided on the outer peripheral portion of the sealing surface 50a facing the process module 110 (the process-side space 16) in the valve body 50.

The sealing material 51 is formed of a rubber material, an elastomer, or the like that is elastically deformable and has high heat resistance, and constitutes an O-ring that extends around the outer peripheral portion of the sealing surface 50a. The sealing material 51 comes to face the contact surface 17 of the block body 12 when being raised by the first moving mechanism 30, and is pressed against the contact surface 17 by the movement in the contact direction by the second moving mechanism 40. This makes it possible for the gate valve 1 to stably seal the process-side space 16 and the processing space 111a of the process module 110.

The gate valve 1 according to the present embodiment has a configuration in which the valve body 50 is moved to the process module 110 for sealing, but may have a configuration in which the valve body 50 is moved to the transport module 120 for sealing. In addition, the operation mechanism part 25 of the gate valve 1 is not limited to being fixed to the process module 110, and may be fixed to the transport module 120.

As the controller 60 of the gate valve 1, a control board including one or more processors 61, a memory 62, an input/output interface (not illustrated), and an electronic circuit is applicable. The controller 60 is fixed to, for example, the bottom wall 114 of the processing container 111 or the base 20. The processor 61 is one of or a combination of two or more of circuits including a CPU, an ASIC, a FPGA, a plurality of discrete semiconductors, and the like. The memory 62 includes a volatile memory and a nonvolatile memory, and stores a program for operating the gate valve 1. The controller 160 of the substrate processing system 100 may also serve as the controller 60 of the gate valve 1.

The gate valve 1 according to the first embodiment is basically formed as described above, and the operation and effect thereof will be described below.

At the time of processing a wafer W by the process module 110, the substrate processing system 100 performs opening/closing of the boundary portion 10 between the process module 110 and the transport module 120 by operating the gate valve 1. The gate valve 1 makes it possible to implement the vacuum atmosphere and the temperature increase inside the processing container 111 by closing the processing container 111 of the process module 110. The gate valve 1 also makes it possible to transport a wafer W between the process module 110 and the transport module 120 by opening the processing container 111 of the process module 110.

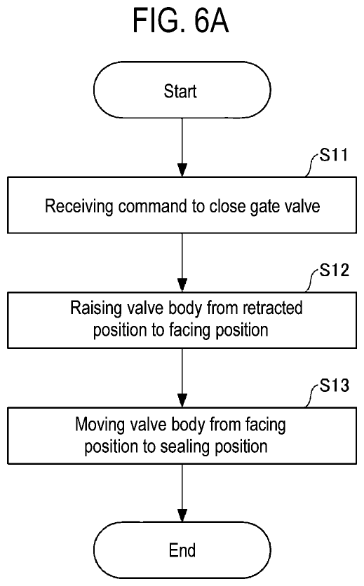

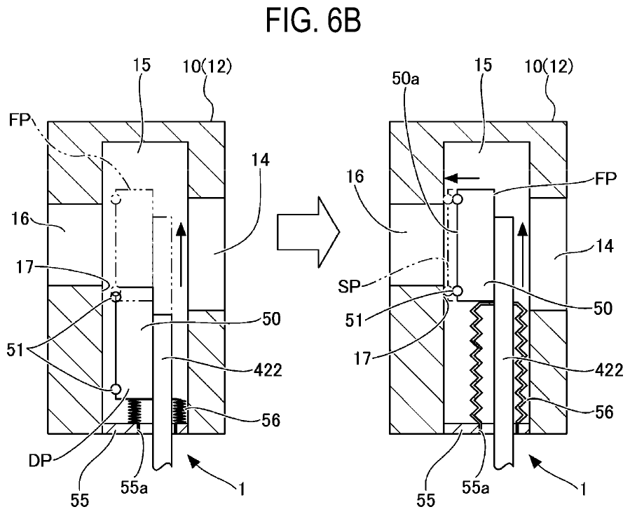

FIG. 6A is a flowchart illustrating the closing operation of the gate valve 1, and FIG. 6B is an explanatory view illustrating the closing operation of the valve body 50. As illustrated in FIG. 6A, the controller 60 of the gate valve 1 initiates the closing operation based on receiving a command to close the gate valve 1 from the controller 160 of the substrate processing system 100 (step S11). Before the initiation of the closing operation, the valve body 50 of the gate valve 1 stands by at a retracted position DP set below the accommodation space 15 of the boundary portion 10. As a result, the process-side space 16 is fully opened with respect to the accommodation space 15.

When the controller 60 initiates the closing operation, the controller 60 operates the first moving mechanism 30 to raise the valve body 50 from the retracted position DP to the facing position FP at which the valve body 50 faces the process-side space 16 (step S12). At this time, the controller 60 outputs a command for a preset operating speed and an operating time to the motor driver, so that the motor driver supplies appropriate power to the motor 331 of the first moving mechanism 30. In other words, the controller 60 raises and lowers the valve body 50 by feedforward control. The gate valve 1 may be configured to recognize and control the lifting position of the valve body 50 by a feed-back of the rotation speed or the like from the motor 331.

The first moving mechanism 30 guides the displacement of the vertical movement body 32 by the linear motion bearing 35 (the pair of vertical guide rails 31 and the guide members 34) upward in the vertical direction (to one side of the first linear track), thereby linearly raising the vertical movement body 32. As a result, the valve body 50 supported by the vertical movement body 32 via the horizontal movement body 42 is smoothly movable from the retracted position DP toward the facing position FP without coming into contact with the inner surface of the block body 12 in the accommodation space 15 of the block body 12.

When the valve body 50 reaches the facing position FP, the controller 60 operates the second moving mechanism 40 to move (advance) the valve body 50 from the facing position FP to the sealing position SP (step S13). At this time, the controller 60 outputs a command for a preset operating speed and an operating time to the motor driver, so that the motor driver supplies appropriate power to the motor 431 of the second moving mechanism 40. The gate valve 1 may have a configuration in which the second moving mechanism 40 also recognizes and controls the advanced position of the valve body 50 by a feed-back of the rotation speed or the like from the motor 431.

The second moving mechanism 40 linearly and finely feeds the horizontal movement body 42 toward the contact direction of the contact surface 17 (one side of the second linear track) by operating the differential screw mechanism 430 (the first screw 432, the second screw 433, and slider 434) as the motor 431 rotates. At this time, the second moving mechanism 40 linearly slides the horizontal movement body 42 along the contact/separation direction by guiding the displacement of the horizontal movement body 42 by the linear motion bearing 45 (the pair of horizontal guide rails 41 and the guide members 44). That is, the second moving mechanism 40 makes a relationship between the displacement of the horizontal movement body 42 from the reference position of the horizontal movement body 42 and the time coincide with a relationship between the displacement of the valve body 50 from the reference position of the valve body 50 and the time. The relationship between the displacement of the horizontal movement body 42 from the reference position of the horizontal movement body 42 and time is determined depending on, for example, the operating direction, the operating amount, the operating speed, the time change of the operating speed, the operating force (including the operating torque), and the time change of the operating force (including the operating torque) of the horizontal actuator 43. As a result, as illustrated in FIG. 6B, the sealing material 51 of the valve body 50 that has moved to the sealing position SP comes into contact with the entire circumference of the contact surface 17 around the process-side space 16 so that the space between the accommodation space 15 and the process-side space 16 can be uniformly sealed.

In the above-described closing operation, the valve body 50 of the gate valve 1 sequentially moves at two-step timings of the movement in the ascending direction (to one side of the first linear track) and the movement in the contact direction (to one side of the second linear track). Therefore, when the contact surface 17 is sealed by the sealing material 51, the sealing material 51 is pressed only from the direction orthogonal to the contact surface 17 (contact direction). Therefore, the problems such as the rubbing of the sealing material 51 due to the oblique movement of the valve body 50 are eliminated, and thus it is possible to improve the durability of the sealing material 51. In addition, the gate valve 1 is capable of appropriately adjusting the pressing force of the valve body 50 on the contact surface 17 by moving the valve body 50 with a short movement amount by the differential screw mechanism 430.

Here, in the gate valve disclosed in Patent Document 1, the first drive device and the second drive device are provided at different positions. Moreover, in the second drive device, the pressing direction of the valve body at the time of sealing and the direction in which the rod of the second drive device moves (advances) are different from each other. For this reason, the mechanism as the entire gate valve may become large, and the pressing direction and pressing force of the valve body may not be smoothly transferred to the sealing material. For example, since the valve body is obliquely inclined and sealed by the rod of the second drive device, the pressing direction and the pressing force become unstable. In addition, in the gate valve disclosed in Patent Document 2, a stepped sealing material is installed on the valve body, but in this case, the opposite sealing materials of the valve body in the width direction are inclined with respect to the contact surface, which will result in deterioration of sealing performance.

In contrast, the gate valve 1 according to the first embodiment includes an operation mechanism part 25 on the lower side of the boundary portion 10 and the process module 110 (a position adjacent to the exterior thereof), and the first moving mechanism 30 has the second moving mechanism 40 mounted thereon. Therefore, the gate valve 1 does not includes a mechanism related to the movement of the valve body 50 in the boundary portion 10. Thus, it is possible to narrow the boundary portion 10, and it is also possible to reduce the size of the entire gate valve 1 as small as possible. Furthermore, in the gate valve 1, since the second linear track of the second moving mechanism 40 and the sealing direction of the valve body 50 are coincident (parallel), the movement vector of the second moving mechanism 40 can be smoothly transmitted to the valve body 50 as the pressing direction and the pressing force of the valve body 50. As a result, the sealing performance of the valve body 50 can be further improved.

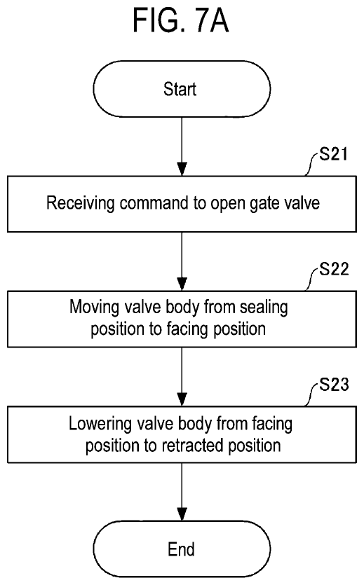

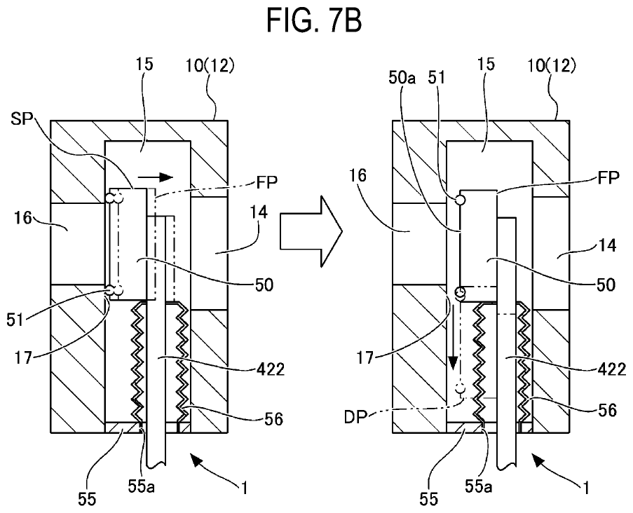

FIG. 7A is a flowchart illustrating the opening operation of the gate valve 1, and FIG. 7B is an explanatory view illustrating the opening operation of the valve body 50. As illustrated in FIG. 7A, the controller 60 of the gate valve 1 initiates the opening operation based on receiving a command to open the gate valve 1 from the controller 160 before or after the process in the process module 110 (step S21). At the initiation of the opening operation, the valve body 50 of the gate valve 1 seals the contact surface 17 at the sealing position SP, and the process-side space 16 is in the state of being completely closed with respect to the accommodation space 15.

When the controller 60 initiates the opening operation, the second moving mechanism 40 is first operated to move (retract) the valve body 50 from the sealing position SP to the facing position FP (step S22). The second moving mechanism 40 slides the horizontal movement body 42 linearly from the contact surface 17 toward the separation direction (the other side of the second linear track) with the reverse rotation of the motor 431. As a result, sticking of the contact surface 17 and the sealing material 51 is suppressed, and the valve body 50 is easily separated in the direction opposite to the pressing direction.

When the valve body 50 reaches the facing position FP, the controller 60 operates the first moving mechanism 30 to lower the valve body 50 from the facing position FP to the retracted position DP (step S23). With the rotation of the motor 331, the first moving mechanism 30 linearly displaces the vertical movement body 32 in the descending direction (the other side of the first linear track). Therefore, as illustrated in FIG. 7B, the valve body 50 can be smoothly moved to the retracted position DP without coming into contact with the inner surface in the accommodation space 15 in the block body 12.

That is, even in the opening operation, the gate valve 1 moves the valve body 50 at two-step timings of the movement in the separation direction (to the other side of the second linear track) and the movement in the descending direction (to the other side of the first linear track). Therefore, the gate valve 1 smoothly separates the sealing material 51 from the contact surface 17 to eliminate problems such as rubbing of the sealing material 51 so that the durability of the sealing material 51 can be improved.

The gate valve 1 is not limited to the above-described embodiments, and various modifications can be adopted. For example, the gate valve 1 may directly detect a change in the amount of movement or pressing force of the valve body 50 in the contact direction to predict the state of the sealing material 51 (amount of wear, amount of sagging, and the like) and adjust the moving position (pressing force) of the sealing material 51.

As an example, the gate valve 1 includes a position sensor (not illustrated) that detects the position of the valve body 50 in the contact/separation direction, a load sensor (not illustrated) that detects a load applied to the valve body 50, and the like. Then, the controller 60 acquires the position information from the position sensor and the load information from the load sensor, and predicts the state of the sealing material 51 with reference to map information (not illustrated) prepared in advance. In addition, when the controller 60 predicts that the amount of wear of the sealing material 51 increases, the controller 60 corrects the target position of the movement in the contact direction by the second moving mechanism 40 to a position closer to the contact surface 17. As a result, even if the sealing material 51 is worn during the operation of the substrate processing system 100, the gate valve 1 may satisfactorily adjust the operation of the valve body 50 to supplement the sealing performance of the sealing material 51.

### Second Embodiment

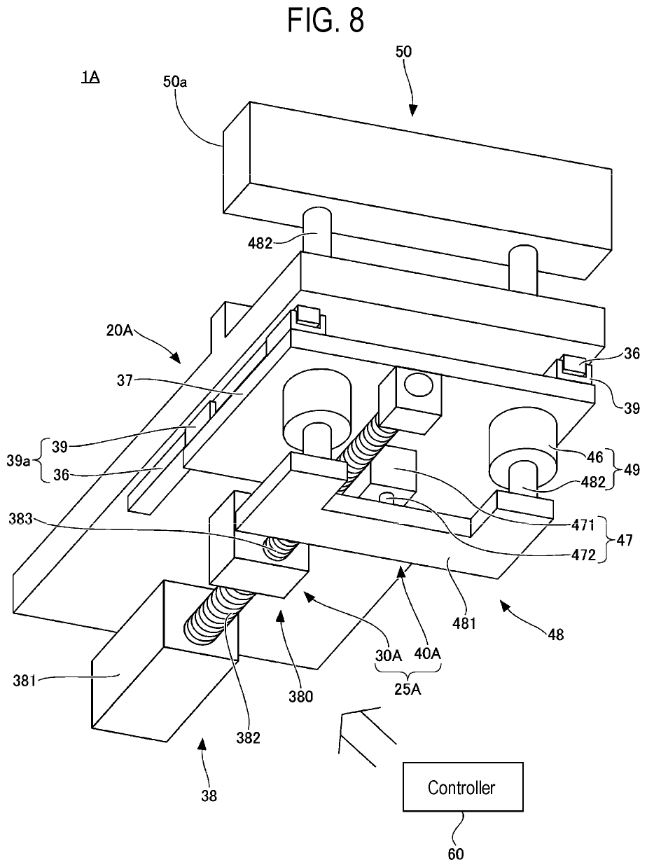

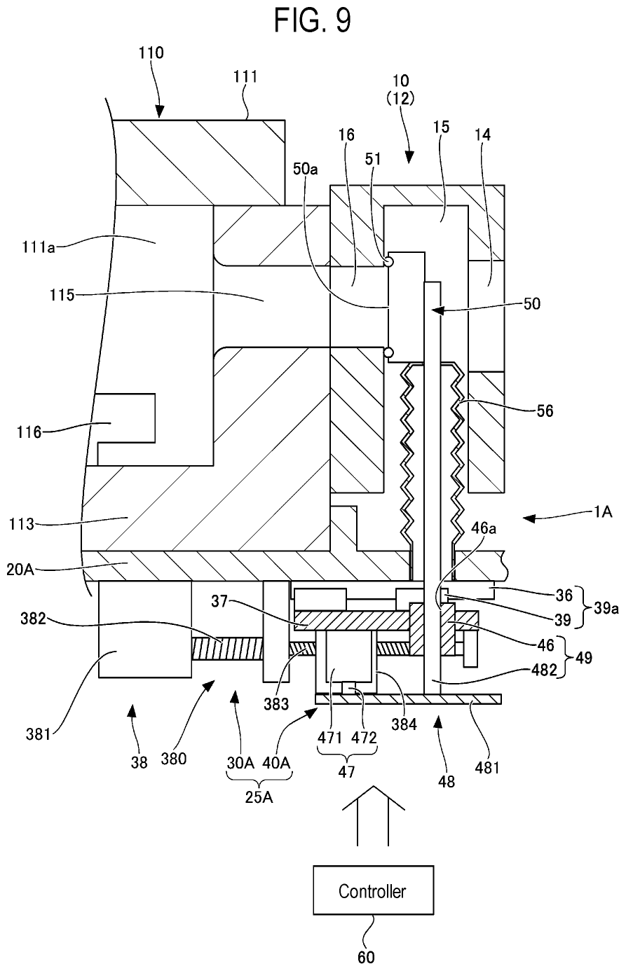

FIG. 8 is a schematic perspective view illustrating each component of a gate valve 1A according to a second embodiment. FIG. 9 is a schematic side view of the gate valve 1A of FIG. 8. As illustrated in FIGS. 8 and 9, the gate valve 1A is different from the gate valve 1 according to the first embodiment in that a first moving mechanism 30A moves in the contact/separation direction and a second moving mechanism 40A fixed to the first moving mechanism 30A moves in the vertical direction.

Specifically, the gate valve 1A includes a base 20A that fixes an operation mechanism part 25A of the gate valve 1A outside and below the process module 110. The base 20A is formed in a plate shape extending in the horizontal direction and installed on the bottom wall 114 of the processing container 111. The base 20A extends from the process module 110 to the boundary portion 10 and covers an open portion 15a of the block body 12, thereby also serving as a closing member 55 (see FIG. 2) that closes the accommodating space 15. In addition, the gate valve 1A (and the gate valve 1) may not include a member functioning as the base 20 or 20A, and the first moving mechanism 30A may be directly installed on the process module 110 or the transport module 120. In this case, the processing container 111 of the process module 110 or the housing 122 of the transport module 120 corresponds to the base 20 or 20A of the present disclosure.

The first moving mechanism 30A includes horizontal guide rails 36 that are installed on the base 20A, a horizontal movement body 37 that moves along the horizontal guide rail 36, and a horizontal actuator 38 that moves the horizontal movement body 37. A plurality (a pair) of horizontal guide rails 36 are installed on the base 20A and extend parallel to each other along the contact/separation direction. The horizontal movement body 37 includes, on the top surface thereof, guide members 39 that extend in parallel with the base 20A and the horizontal guide rails 36 and are slidably engaged with respective horizontal guide rails 36, and a second moving mechanism 40A is installed on the bottom surface thereof. That is, the horizontal guide rails 36 and the guide members 39 form a linear motion bearing 39a.

The horizontal actuator 38 reciprocates the horizontal movement body 37 along the contact/separation direction (the first linear track). A ball screw drive part including a differential screw mechanism 380 is also applied to the horizontal actuator 38. The horizontal actuator 38 includes a motor 381 fixed to the base 20A, a first screw 382 connected to the motor 381, a second screw 383 screw-coupled to the interior of the first screw 382, and a slider 384 screw-coupled to the second screw 383 and fixed to the horizontal movement body 42.

On the other hand, the second moving mechanism 40A includes cylindrical guide portions 46 and a vertical actuator 47 fixed to the horizontal movement body 37, and a vertical movement body 48 fixed to the vertical actuator 47. The vertical movement body 48 is provided with a plurality (e.g., a pair) of supports 482 that support the valve body 50.

The cylindrical guide portions 46 and the supports 482 are provided on opposite sides of the horizontal movement body 37 in the width direction. The cylindrical guide portions 46 protrude shortly downward from the horizontal movement body 37 in the vertical direction, and the supports 482 are inserted into guide holes 46a provided in the centers of the cylindrical guide portions 46, respectively, so that the upward/downward movement of the supports 482 is guided in the vertical direction. That is, the cylindrical guide portions 46 and the supports 482 constitute a linear motion bearing 49 in the vertical direction. Various bearing structures such as ball bearings, spline bearings, and other slide bearings may be applied to the guide holes 46a and the supports 482.

For example, an air cylinder (a fluid pressure cylinder) may be applied to the vertical actuator 47. In this case, the vertical actuator 47 includes a cylinder portion 471, an air mechanism (not illustrated) that allows air to flow into and out of the cylinder portion 471, and a rod 472 that is disposed in the axial center of the cylinder portion 471 and moves forward and backward by air pressure. In the present embodiment, the rod 472 extends downward in the vertical direction, and the vertical movement body 48 is fixed at the extension end (lower end) of the rod 472.

The vertical movement body 48 includes a plate-shaped drive transmission member 481 extending in the width direction below the horizontal movement body 37, and the supports 482 connected to the drive transmission member 481. In the drive transmission member 481, the rod 472 is fixed to the central portion in the width direction, while the supports 482 are respectively fixed to the opposite sides in the width direction.

Based on the control of the controller 60, the gate valve 1A configured as described above linearly raises/lowers the valve body 50 between the retracted position DP and the facing position FP along the vertical direction (the second linear track) by the second moving mechanism 40A. That is, the vertical actuator 47 lowers the valve body 50 via the vertical movement body 48 and the supports 482 by advancing the rod 472 downward, and raises the valve body 50 via the vertical movement body 48 and the supports 482 by retracting the rod 472 upward.

Then, after raising the valve body 50 and disposing the valve body 50 at the facing position FP, the gate valve 1A moves the valve body 50 from the facing position FP to the contact position by the first moving mechanism 30A, and presses the sealing material 51 of the valve body 50 against the contact surface 17. The first moving mechanism 30A finely feeds the valve body 50 by the differential screw mechanism 380. At this time, the first moving mechanism 30A guides the displacement of the horizontal movement body 37 by the linear motion bearing 39a, so that the horizontal movement body 37 slides linearly along the contact/separation direction. That is, the first moving mechanism 30A makes a relationship between the displacement of the horizontal movement body 37 from a reference position of the horizontal movement body 37 and time coincide with a relationship between the displacement of the valve body 50 from a reference position of the valve body 50 and time. The relationship between the displacement of the horizontal movement body 37 from the reference position of the horizontal movement body 37 and time is determined depending on, for example, the operating direction, the operating amount, the operating speed, the time change of the operating speed, the operating force (including the operating torque), and the time change of the operating force (including the operating torque) of the horizontal actuator 38. As a result, the first moving mechanism 30A is capable of pressing the sealing material 51 of the valve body 50 against the contact surface 17 in an appropriate pressing direction and pressing force.

As described above, even with the gate valve 1A according to the second embodiment, it is possible to control the pressing direction and the pressing force of the valve body 50 with high accuracy by the first moving mechanism 30A and the second moving mechanism 40A and to enhance the durability of the sealing material 51.

The technical ideas and effects of the present disclosure described in the above-described embodiments will be described below.

The first aspect of the present disclosure is a gate valve 1 or 1A provided in a boundary portion 10 between two sections to block communication between the two sections, wherein the gate valve 1 or 1A includes: a base 20 or 20A; a first moving mechanism 30 or 30A installed on the base 20 or 20A and configured to move a first movement body (the vertical movement body 32, the horizontal movement body 37) along a first linear track; a second moving mechanism 40 or 40A installed on the first movement body, configured to operate at a timing different from that of the first moving mechanism 30 or 30A and to move a second movement body (the horizontal movement body 42, the vertical movement body 48) along a second linear track orthogonal to the first linear track; and a valve body 50 installed on the second movement body to come into contact with a contact surface 17 so as to perform sealing, wherein one of the first linear track and the second linear track is parallel to a direction orthogonal to the contact surface 17.

The above-described gate valve 1 or 1A is capable of accurately controlling the pressing direction and pressing force at the time of sealing by linearly moving the valve body 50 in two directions by the first moving mechanism 30 and the second moving mechanism 40. That is, the gate valve 1 or 1A is capable of stably (with high reproducibility) pressing the sealing material 51 against the contact surface 17 by moving the valve body 50 in parallel in a direction (contact direction) orthogonal to the contact surface 17. As a result, the gate valve 1 or 1A is capable of suppressing rubbing and sticking of the sealing material 51 of the valve body 50 to improve the durability of the sealing material 51 compared with the sealing operation using the conventional link mechanism or the like.

In addition, the first moving mechanism 30 or 30A and the second moving mechanism 40 or 40A are provided at positions adjacent to the outside of the boundary portion 10. This makes it possible to reduce the thickness of the boundary portion 10 of the gate valve 1 or 1A as much as possible so that the miniaturization of the system provided with the gate valve 1 or 1A can be promoted.

In addition, one of the two sections is a processing space 111a of the processing container 111 for processing a substrate, and at least the first moving mechanism 30 is provided below the processing container 111. In the gate valve 1 or 1A, since a portion of the operating mechanism part 25 or 25A configured to move the valve body 50 is located below the processing container 111, it is possible to further miniaturize the boundary portion 10.

In addition, the boundary portion 10 includes an accommodation space 15 in which the valve body 50 is movably accommodated, the valve body 50 and the second movement body (the horizontal movement body 42, the vertical movement body 48) are connected to each other via a support 422 or 482 extending from the outside of the boundary portion 10 to the accommodation space 15, and the bellows 56 extending from a portion that closes the accommodation space 15 into the accommodation space 15 while surrounding the support 422 or 482 is provided around the support 422 or 482. This makes it possible to install the first moving mechanism 30 or 30A and the second moving mechanism 40 or 40A, which are connected to the interior of the bellows 56, on the atmosphere side, and thus it is possible to stably operate the first moving mechanism 30 or 30A and the second moving mechanism 40 or 40A of the gate valve 1 or 1A. In particular, when the valve body 50 is disposed in a space that has a vacuum atmosphere or is supplied with gas, the gate valve 1 or 1A is capable of suppressing a change in the state of the space.

In addition, the first moving mechanism 30 or 30A and the second moving mechanism 40 or 40A include linear motion bearings 35 or 39a and 45 or 49, respectively. This makes it possible for the gate valve 1 or 1A to smoothly move the valve body 50 along the first linear track and the second linear track.

In addition, one of the first moving mechanism 30 or 30A and the second moving mechanism 40 or 40A that moves the valve body 50 toward the contact surface 17 includes a differential screw mechanism 380 or 430 that is capable of finely feeding the valve body 50. This makes it possible for the gate valve 1 or 1A to move the valve body 50 more accurately when the valve body 50 is brought into contact with the contact surface 17, and to appropriately control the pressing force at the time of sealing.

In addition, the first moving mechanism 30 raises/lowers the first movement body (the vertical movement body 32) in the vertical direction as the first linear track, and the second moving mechanism 40 moves the second movement body (the horizontal movement body 42) in parallel to a direction orthogonal to the contact surface 17 as the second linear track. This makes it possible for the gate valve 1 to smoothly perform sealing by raising the valve body 50 by the first moving mechanism 30 and then moving the valve body 50 toward the contact surface 17 by the second moving mechanism 40.

In addition, the base 20 extends along the vertical direction, the first moving mechanism 30 includes a vertical guide rail 31 provided on the base 20 and a vertical actuator 33 configured to move the first movement body (the vertical movement body 32) along the vertical guide rail 31, the first movement body includes a vertically extending portion (the vertical frame portion 321) extending in the vertical direction and a horizontally extending portion (the horizontal table portion 322) connected to the vertically extending portion and extending in the horizontal direction, and the second moving mechanism 40 includes a horizontal guide rail 41 provided on the horizontally extending portion and a horizontal actuator 43 configured to move the second movement body (the horizontal movement body 42) along the horizontal guide rail 41. This makes it possible for the gate valve 1 to more smoothly perform the movement of the valve body 50 along the two tracks.

In addition, the second moving mechanism 40 makes the relationship between the displacement of the second movement body (the horizontal movement body 42) from a reference position of the second movement body and time coincide with the relationship between the displacement of the valve body 50 from a reference position of the valve body and time. This makes it possible for the gate valve 1 to smoothly converts the operation of the second moving mechanism 40 into the operation of the valve body 50. As a result, it is possible to more stably operate the valve body 50 compared with a configuration in which a mechanism (e.g., a link mechanism) in which a plurality of mechanical elements does not match in operation is applied.

The first moving mechanism 30A moves the first movement body (the horizontal movement body 37) in parallel to a direction orthogonal to the contact surface 17 as the first linear track, and the second moving mechanism 40A raises/lowers the second movement body (the vertical movement body 48) in the vertical direction as the second linear track. This makes it possible for the gate valve 1A to smoothly perform sealing by raising the valve body 50 by the second moving mechanism 40A and then moving the valve body 50 toward the contact surface 17 by the first moving mechanism 30A.

In addition, the base 20A extends along the horizontal direction, the first moving mechanism 30A includes a horizontal guide rail 36 provided on the base 20, a horizontal actuator 38 configured to move the first movement body (the horizontal movement body 37) along the horizontal guide rail 36, and the second moving mechanism 40A includes a vertical guide member (cylindrical guide portion) provided on the first movement body and a vertical actuator 47 configured to move the second movement body (the vertical movement body 48) along the vertical guide rail. This also makes it possible for the gate valve 1A to more smoothly perform the movement of the valve body 50 along the two tracks.

In addition, the first moving mechanism 30A makes the relationship between the displacement of the first movement body (the horizontal movement body 37) from a reference position of the first movement body and time coincide with the relationship between the displacement of the valve body 50 from a reference position of the valve body 50 and time. This makes it also possible for the gate valve 1A to smoothly convert the operation of the first moving mechanism 30A into the operation of the valve body 50.

In addition, the gate valves 1 and 1A are provided in a semiconductor manufacturing apparatus. This makes it possible for the gate valves 1 and 1A to control the opening/closing of a semiconductor manufacturing space in the semiconductor manufacturing apparatus with high accuracy. Thus, the durability of the valve body 50 is enhanced. Therefore, with the gate valves 1 and 1A, it is possible to lengthen the maintenance cycle of the semiconductor manufacturing apparatus.

A second aspect of the present disclosure is a substrate processing system 100 including a process module 110 configured to process a substrate, a transport module 120 configured to transport the substrate (a wafer W) to the process module 110, and a gate valve 1 or 1A provided in a boundary portion 10 between the process module 110 and the transport module 120, wherein the gate valve 1 or 1A includes: a base 20 or 20A; and a first moving mechanism 30 or 30A installed on the base 20 or 20A and configured to reciprocate a first movement body (the vertical movement body 32, the horizontal movement body 37) along a first linear track; a second moving mechanism 40 or 40A installed on the first movement body and configured to operate at a timing different from the first moving mechanism 30 or 30A so as to reciprocate a second movement body (the horizontal movement body 42, the vertical movement body 48) along a second linear track orthogonal to the first linear track; and a valve body 50 installed on the second movement body and configured to come into contact with a contact surface 17 so as to perform sealing, wherein one of the first linear track and the second linear track is parallel to a direction orthogonal to the contact surface 17.

In addition, a third aspect of the present disclosure is a method of operating a gate valve 1 or 1A provided in a boundary portion 10 between two sections to block communication between the two sections, wherein the gate valve 1 or 1A includes: a base 20 or 20A; a first moving mechanism 30 or 30A installed on the base 20 or 20A and configured to move a first movement body (the vertical movement body 32, the horizontal movement body 37) along a first linear track; a second moving mechanism 40 or 40A installed on the first movement body and configured to operate at a timing different from that of the first moving mechanism 30 or 30A so as to move a second movement body (the horizontal movement body 42, the vertical movement body 48) along a second linear track orthogonal to the first linear track; and a valve body 50 installed on the second movement body to come into contact with a contact surface 17 so as to perform sealing, wherein one of the first linear track and the second linear track is parallel to a direction orthogonal to the contact surface 17, and wherein the method includes: a first step of moving the valve body 50 from a retracted position DP to a facing position FP by operating one of the first moving mechanism 30 or 30A and the second moving mechanism 40 or 40A first; and after the first step, a second step of moving the valve body 50 from the facing position FP to a sealing position SP at which the valve body 50 comes into contact with the contact surface 17 by operating the other of the first moving mechanism 30 or 30A and the second moving mechanism 40 or 40A.

In the second and third aspects as well, it is possible to control the pressing direction and pressing force at the time of sealing with high accuracy.

The gate valves 1 and 1A according to the embodiment disclosed herein are exemplary in all respects and not restrictive. The embodiments may be modified and improved in various forms without departing from the scope and spirit of the appended claims. The matters described in in the plurality of embodiments may take other configurations within a non-contradictory range, and may be combined within a non-contradictory range.

According to an aspect, it is possible to control the pressing direction and the pressing force at the time of sealing with high accuracy.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gate valve provided in a boundary portion between two sections to block communication between the two sections, the gate valve comprising:
a base;
a first moving mechanism installed on the base and configured to move a first movement body along a first linear track;
a second moving mechanism installed on the first movement body, and configured to operate at a timing different from the first moving mechanism and to move a second movement body along a second linear track orthogonal to the first linear track; and
a valve body installed on the second movement body and configured to come into contact with a contact surface so as to perform sealing,
wherein one of the first linear track and the second linear track is parallel to a direction orthogonal to the contact surface.

2. The gate valve of claim 1, wherein the first moving mechanism and the second moving mechanism are provided at positions adjacent to an outside of the boundary portion.

3. The gate valve of claim 2, wherein one of the two sections is a processing space of a processing container configured to process a substrate, and
at least the first moving mechanism is provided below the processing container.

4. The gate valve of claim 3, wherein the boundary portion includes an accommodation space in which the valve body is movably accommodated,
the valve body and the second movement body are connected to each other via a support extending from the outside of the boundary portion into the accommodation space, and
a bellows provided around the support to extend from a portion closing the accommodation space into the accommodation space while surrounding the support.

5. The gate valve of claim 4, wherein the first moving mechanism and the second moving mechanism include linear motion bearings, respectively.

6. The gate valve of claim 5, wherein one of the first moving mechanism and the second moving mechanism that moves the valve body toward the contact surface includes a differential screw mechanism configured to finely feed the valve body.

7. The gate valve of claim 6, wherein the first moving mechanism is configured to raise/lower the first movement body in a vertical direction as the first linear track, and
the second moving mechanism is configured to move the second movement body in parallel to the direction orthogonal to the contact surface as the second linear track.

8. The gate valve of claim 7, wherein the base extends along the vertical direction,
the first moving mechanism includes a vertical guide rail provided on the base and a vertical actuator configured to move the first movement body along the vertical guide rail,
the first movement body includes a vertically extending portion extending in the vertical direction and a horizontally extending portion connected to the vertically extending portion and extending in a horizontal direction, and
the second moving mechanism includes a horizontal guide rail provided on the horizontally extending portion and a horizontal actuator configured to move the second movement body along the horizontal guide rail.

9. The gate valve of claim 8, wherein the second moving mechanism is configured to make a relationship between a displacement of the second movement body from a reference position of the second movement body and time coincide with a relationship between a displacement of the valve body from a reference position of the valve body and time.

10. The gate valve of claim 7, wherein the second moving mechanism is configured to make a relationship between a displacement of the second movement body from a reference position of the second movement body and time coincide with a relationship between a displacement of the valve body from a reference position of the valve body and time.

11. The gate valve of claim 2, wherein the boundary portion includes an accommodation space in which the valve body is movably accommodated,
the valve body and the second movement body are connected to each other via a support extending from the outside of the boundary portion into the accommodation space, and
a bellows provided around the support to extend from a portion closing the accommodation space into the accommodation space while surrounding the support.

12. The gate valve of claim 1, wherein the first moving mechanism and the second moving mechanism include linear motion bearings, respectively.

13. The gate valve of claim 1, wherein one of the first moving mechanism and the second moving mechanism that moves the valve body toward the contact surface includes a differential screw mechanism configured to finely feed the valve body.

14. The gate valve of claim 1, wherein the first moving mechanism is configured to raise/lower the first movement body in a vertical direction as the first linear track, and the second moving mechanism is configured to move the second movement body in parallel to the direction orthogonal to the contact surface as the second linear track.

15. The gate valve of claim 1, wherein the first moving mechanism is configured to move the first movement body in parallel to the direction orthogonal to the contact surface as the first linear track, and
the second moving mechanism is configured to raise/lower the second movement body in a vertical direction as the second linear track.

16. The gate valve of claim 15, wherein the base extends along a horizontal direction, and
the first moving mechanism includes a horizontal guide rail provided on the base and a horizontal actuator configured to move the first movement body along the horizontal guide rail, and
the second moving mechanism includes a vertical guide member provided on the first movement body and a vertical actuator configured to move the second movement body along the vertical guide member.

17. The gate valve of claim 15, wherein the first moving mechanism is configured to make a relationship between a displacement of the first movement body from a reference position of the first movement body and time coincide with a relationship between a displacement of the valve body from a reference position of the valve body and time.

18. The gate valve of claim 1, wherein the gate valve is provided in a semiconductor manufacturing apparatus.

19. A substrate processing system comprising:
a process module configured to process a substrate;
a transport module configured to transport the substrate to the process module; and
a gate valve provided in a boundary portion between the process module and the transport module,
wherein the gate valve includes:
a base; and
a first moving mechanism installed on the base and configured to move a first movement body along a first linear track;
a second moving mechanism installed on the first movement body and configured to operate at a timing different from the first moving mechanism so as to move a second movement body along a second linear track orthogonal to the first linear track; and
a valve body installed on the second movement body and configured to come into contact with a contact surface so as to perform sealing,
wherein one of the first linear track and the second linear track is parallel to a direction orthogonal to the contact surface.

20. A method of operating a gate valve provided in a boundary portion between two sections to block communication between the two sections,
wherein the gate valve includes:
a base; and
a first moving mechanism installed on the base and configured to move a first movement body along a first linear track;
a second moving mechanism installed on the first movement body, and configured to operate at a timing different from the first moving mechanism and to move a second movement body along a second linear track orthogonal to the first linear track; and
a valve body installed on the second movement body and configured to come into contact with a contact surface so as to perform sealing,
wherein one of the first linear track and the second linear track is parallel to a direction orthogonal to the contact surface, and
wherein the method comprises:
a first step of moving the valve body from a retracted position to a facing position by operating one of the first moving mechanism and the second moving mechanism first; and
after the first step, a second step of moving the valve body from the facing position to a sealing position at which the valve body comes into contact with the contact surface by operating the other of the first moving mechanism and the second moving mechanism.
